(19) United States
(12) Patent Application Publication
(10) Pub. No.: US 2025/0206037 A1
(43) Pub. Date: Jun. 26, 2025

(54) ASSEMBLY FOR PROCESSING REFERENCE POINT, APPARATUS FOR DISPENSING CHEMICAL SOLUTION INCLUDING THE ASSEMBLY AND METHOD FOR DISPENSING CHEMICAL SOLUTION USING THE APPARATUS

(71) Applicant: SEMES CO., LTD., Cheonan-si (KR)

(72) Inventor: Yaejin BYEON, Cheonan-si (KR)

(73) Assignee: SEMES CO., LTD., Cheonan-si (KR)

(21) Appl. No.: 18/953,319

(22) Filed: Nov. 20, 2024

(30) Foreign Application Priority Data
Dec. 26, 2023 (KR) 10-2023-0191966

(51) Int. Cl. B41J 3/46; B41J 2/045; B41J 3/407

(52) U.S. Cl. CPC B41J 3/46; B41J 2/04558; B41J 3/407

(57) ABSTRACT

An apparatus for dispensing chemical solution includes: a printing unit configured to perform a chemical solution discharge process using an inkjet head, a maintenance unit that maintenance is performed on the inkjet head, and a reference point confirming unit including a reference point generating unit and a reference point confirming unit. The reference point generating unit is configured to generate a first reference point provided as a reference point when measuring discharge dot of chemical solution discharged from the inkjet head and a second reference point provided as a reference point when setting a measurement unit used for measuring the discharge dot. The reference point generating unit is configured to generate the first reference point and the second reference point to have a same central axis at a same position while having different sizes. The reference point confirming unit is configured to confirm both the first reference point and the second reference point using only one in one place.

### CROSS-REFERENCE TO RELATED APPLICATION(S)

This application claims priority to and benefits of Korean Patent Application No. 10-2023-0191966 under 35 U.S.C. § 119, filed on Dec. 26, 2023, in the Korean Intellectual Property Office (KIPO), the entire contents of which are incorporated herein by reference.

### BACKGROUND

### 1. Technical Field

Embodiments relate to an assembly for processing reference point, an apparatus for dispensing chemical solution including the assembly, and a method for dispensing chemical solution using the apparatus. More particularly, embodiments relate to an assembly for processing reference point for generating and confirming a reference point for measuring a discharge point of chemical solution dispensed from an inkjet head and a reference point for setting up a measurement unit used to measure discharge point, an apparatus for dispensing chemical solution including the assembly, and a method for dispensing chemical solution using the apparatus.

### 2. Description of the Related Art

Display element such as OLED, QLED, and/or the like are continuously moving toward a trend that requires high resolution. In order to manufacture the display element requiring the high resolution, pixels should be formed on a substrate to be more densely disposed per unit area. And for each of the more densely formed pixels, each of chemical solutions should be more accurately discharged.

Accordingly, a discharge point for the inkjet head discharging the chemical solution should also be managed more accurately. Therefore, maintenance on whether the inkjet head discharges the chemical solution with an accurate discharge point may be performed at any time prior to discharging the chemical solution to the pixels.

Measurement of the discharge point of the inkjet head may be mainly achieved by using a measuring unit such as a JOF unit, and/or the like and may be performed to measure the discharge point of the inkjet head after setting a position of the measuring unit first. Here, a reference point for setting the position of the measuring unit and a reference point for measuring the discharge point of the inkjet head may be same, and the reference point may be confirmed by using a confirming unit such as one camera, and/or the like.

When the one confirming unit is used, the reference point may be easily confirmed without any problem in the discharge point measurement. However, in position setting of the measurement unit, as size of the reference point may be a relatively very small size so that the reference point is outside of field of view (“FOV”) range of the camera, confirming may not be easily performed, and as a result, a situation in which the position setting of the measurement unit may not be performed smoothly may occur.

### SUMMARY

Embodiments provide an assembly for processing a reference point confirming at least two reference points using only one reference point confirming unit.

Embodiments provide an apparatus for dispensing chemical solution including the assembly.

Embodiments provide a method for dispensing chemical solution using the apparatus.

An assembly for processing a reference point according to embodiments may include a reference point generating unit configured to generate at least two reference points of different sizes having a same central axis at a same position and a reference point confirming unit configured to confirm both of the at least two reference points using only one in one place.

In embodiments, the reference point generating unit may be configured to generate the at least two reference points to have a same shape.

In embodiments, the reference point generating unit may include a beam projection for generating one reference point and a size variable unit for changing the one reference point generated by the beam projection to have at least two different sizes.

In embodiments, the reference point confirming unit may include a vision camera, and different sizes for the at least two reference points are within a range satisfying a FOV of the vision camera.

In embodiment, the reference point generating unit may be configured to generate the at least two reference points from below the reference point confirming unit toward the reference point confirming unit.

In embodiments, the reference point confirming unit may be configured to confirm the at least two reference points from above the reference point generating unit toward the reference point generating unit.

An apparatus for dispensing chemical solution according to embodiments may include a printing unit configured to perform a chemical solution discharge process using an inkjet head, a maintenance unit that maintenance is performed on the inkjet head, and a reference point confirming unit.

In embodiments, the reference point confirming unit may include a reference point generating unit and a reference point confirming unit.

In embodiments, the reference point confirming unit may be configured to generate a first reference point provided as a reference point when measuring discharge dot of chemical solution discharged from the inkjet head and a second reference point provided as a reference point when setting a measurement unit used for measuring the discharge dot.

In embodiments, the reference point confirming unit may be configured to generate the first reference point and the second reference point to have a same central axis at a same position while having different sizes.

In embodiments, the reference point confirming unit may be configured to confirm both the first reference point and the second reference point using only one in one place.

In embodiments, the reference point generating unit may be configured to generate the first reference point and the second reference point to have a same shape.

In embodiments, reference point generating unit may be configured to generate the second reference point relatively larger than the first reference point.

In embodiments, the reference point generating unit may include a beam projection for generating one reference point and a size variable unit for changing the one reference point generated by the beam projection into the first reference point and the second reference point having different sizes.

In embodiments, the reference point confirming unit may include a vision camera, and different sizes of the first reference point and the second reference point may be within a range satisfying a FOV of the vision camera.

In embodiments, the printing unit and the maintenance unit may be disposed in parallel along a direction vertical to a transfer direction of a substrate when the chemical solution is discharged.

In embodiments, the inkjet head may be configured to slide on a gantry extending along the printing unit and the maintenance unit.

In embodiments, the reference point processing unit may be provided in the maintenance unit.

In embodiments, the measurement unit may be provided to be disposed in the maintenance unit.

In embodiments, the measurement unit may include a jetting on film (“JOF”) unit configured to supply a test film on which the chemical solution is discharged when the discharge dot is measured.

In embodiments, the reference point processing unit may be fixed to the JOF unit.

In embodiments, the reference point generating unit in the reference point processing unit may be configured to generate the first reference point and the second reference point from bottom of the JOF unit to top of the JOF unit.

In embodiments, the reference point confirming unit may be configured to confirm the first reference point and the second reference point from the top of the JOF unit to the bottom of the JOF unit facing the reference point generating unit.

A method for dispensing chemical solution according to embodiments may include setting a measurement unit used to measure discharge dot of chemical solution discharged from an inkjet head based on a second reference point, and measuring the discharge dot of the chemical solution discharged from the inkjet head based on a first reference point using the measuring unit.

In embodiments, the first reference point and the second reference point may have different sizes and may be generated to have a same central axis at a same position.

In embodiments, both the first reference point and the second reference point may be confirmed using one reference point confirming unit in one place.

In embodiments, the first reference point and the second reference point may have a same shape.

In embodiments, the second reference point may be relatively larger than the first reference point.

In embodiments, the first reference point and the second reference point may be generated by changing one reference point generated by beam projection to have different sizes.

In embodiments, the first reference point and the second reference point may be confirmed by using one vision camera disposed in one place.

In embodiments, different sizes of the first reference point and the second reference point may be within a range satisfying a FOV of the vision camera.

In embodiments, the first reference point and the second reference point may be configured to be generated from bottom of the measurement unit to top of the measurement unit.

In embodiments, the first reference point and the second reference point may be configured to be confirmed from the top of the measurement unit to the bottom of the measurement unit.

As the assembly, the apparatus, and the method according to embodiments may easily confirm at least two reference points using only one reference point confirming unit, it is possible to more easily and accurately set a position of the measuring unit and measure the discharge dot of the inkjet head.

Accordingly, the assembly, the apparatus, and the method according to embodiments may accurately manage the discharge dot of the inkjet head. Accordingly, the assembly, the apparatus and the method according to embodiments may be actively applied to manufacture of display element requiring high resolution as the assembly, the apparatus, and the method may perform more accurate and easier maintenance for the inkjet head to perform the chemical solution discharge process for each of more densely arranged pixels.

### BRIEF DESCRIPTION OF THE DRAWINGS

Illustrative, non-limiting embodiments will be more clearly understood from the following detailed description in conjunction with the accompanying drawings.

FIG. 1 is a schematic diagram for describing an apparatus for dispensing chemical solution according to embodiments.

FIG. 2 is a schematic diagram for explaining a reference point processing unit in the apparatus of FIG. 1.

FIG. 3 is a schematic diagram for describing a reference point generating unit in the reference point processing unit of FIG. 2.

FIG. 4 is a schematic diagram for describing a first reference point and a second reference point generated by using the reference point processing unit of FIG. 2.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

As present invention may make various changes and have various forms, embodiments will be described in detail in text. However, it is not intended to limit the present invention to a specific embodiment, and should be understood as including all changes, equivalents or substitutes included in spirit and technical scope of the present invention. Similar reference numerals were used for similar components while describing each drawing. Terms such as first and second may be used to describe various components, but the components should not be limited by the terms. The terms are used only for purpose of distinguishing one component from another. The terms used in the present application are used only to describe specific embodiments and are not intended to limit the present invention. Singular expressions include plural expressions unless context clearly indicates otherwise. In this application, terms such as “include” are intended to specify existence of features, numbers, steps, actions, components, units, or combinations thereof described in the specification, and should be understood not to preclude existence or addition of one or more other features, numbers, steps, actions, components, units, or combinations thereof.

Unless otherwise defined, all terms used herein, including technical or scientific terms, have same meaning as is generally understood by those of ordinary skill in art to which the present invention pertains. Terms generally defined in dictionary should be interpreted as having meaning consistent with meaning of context of relevant technology and are not interpreted in an ideal or overly formal sense unless explicitly defined in this application. Hereinafter, preferred embodiments of the present invention are to be described in more detail with reference to accompanying drawings.

FIG. 1 is a schematic diagram for describing an apparatus for dispensing chemical solution according to embodiments.

Referring to FIG. 1, an apparatus 100 for dispensing chemical solution according to embodiments may be applied to a discharge process of discharging chemical solution onto a substrate 50 when manufacturing display element such as OLED or QLED, and/or the like, for example, may be applied to a discharge process of discharging each of chemical solution to each pixel formed on the substrate 50. The apparatus 100 may include a structure including a printing unit 11, a maintenance unit 13, a measurement unit 23, a reference point processing unit 31, and/or the like.

The printing unit 11 may be an area for performing a chemical solution discharging process for discharging the chemical solution onto the substrate 50. The printing unit 11 may be an area for performing the chemical solution discharging process for discharging the chemical solution onto the substrate 50 using an inkjet head 19.

The chemical solution discharge process in the printing unit 11 may be performed while the substrate 50 is floating, and the printing unit 11 may be provided with a floating stage 15 floating the substrate 50. If floating height of the substrate 50 in the printing unit 11 is not controlled relatively precisely, it may act as a defect factor when performing the chemical solution discharge process. Accordingly, as the floating height of the substrate 50 in the printing unit 11 must be controlled relatively precisely, the floating stage 15 may be provided not only to supply air toward the substrate 50 but also to have a structure to supply vacuum toward the substrate 50. The floating stage 15 in the printing unit 11 may be provided to have a structure in which air holes for supplying air and vacuum holes for supplying vacuum are provided.

When performing the chemical solution discharge process in the printing unit 11, the substrate 50 may be transferred along the floating stage 15. The chemical solution discharge process in the printing unit 11 may be performed while transferring the substrate 50 along the floating stage 15, and may be performed to pass under the inkjet head 19 so that the chemical solution can be discharged on the substrate 50 transferred along the floating stage 15. A transfer unit 51 is provided to transfer the substrate 50 along the floating stage 15, and may be provided to be disposed on one side, the other side, or both sides of the substrate 50. The transfer unit 51 may be provided to have a structure including a gripping portion for gripping the substrate 50, a guide rail extending to one side or the other side of the floating stage 15 so that the gripping portion may slide along the floating stage 15, a driving unit for supplying a driving force for the gripping portion to slide along the guide rail. The gripping portion may be provided to vacuum-adsorb a rear surface of an end of the substrate 50 or to directly grip the end of the substrate 50.

The maintenance unit 13 may be mainly provided to perform maintenance on the inkjet head 19, and may be provided to perform a chemical solution discharge process for maintenance from the inkjet head 19. In case of the chemical solution discharge process for maintenance in the maintenance unit 13, as it must be performed under process conditions almost similar to the actual chemical solution discharge process, the maintenance unit 13 may be provided to have same or almost similar process environment as the printing unit 11. In addition, the maintenance unit 13 may also be provided with a floating stage 17 having same or almost similar structure as the floating stage 15 in the printing unit 11. In case of the floating stage 17 in the maintenance unit 13, it may be provided to have a structure in which air holes and vacuum holes are provided, and a transfer member having same or almost similar structure as the transfer unit 51 may be provided.

The printing unit 11 and the maintenance unit 13 may be provided to be disposed in parallel along a direction vertical to a transfer direction of the substrate 50. A gantry 27 may be provided to have a structure extending along a vertical direction in which the printing unit 11 and the maintenance unit 13 are disposed. The gantry 27 may be provided to have a structure that crosses the printing unit 11 and the maintenance unit 13 along the vertical direction. The gantry 27 may be provided with a structure extending to have a length sufficient to cover the vertical direction in which the printing unit 11 and the maintenance unit 13 are disposed.

The gantry 27 may be provided such that the inkjet head 19 is disposed. The inkjet head 19 may be provided to have a structure of sliding along the gantry 27. The inkjet head 19 may be provided to slide so as to reciprocate linearly along the gantry 27. That is, the inkjet head 19 may be provided to move between the printing unit 11 and the maintenance unit 13 disposed along the vertical direction according to a set condition, and may be provided to be located in the printing unit 11 when the chemical solution discharge process is performed, and may be provided to be located in the maintenance unit 13 during a maintenance. Although not shown, a chemical solution supply unit for supplying the chemical solution to the inkjet head 19 through the gantry 27 may be provided.

The inkjet head 19 may be provided such that a plurality of nozzles through which the chemical solution is discharged are disposed. The plurality of nozzles disposed on the inkjet head 19 may be arranged in a line at intervals of a predetermined pitch. The nozzles in the inkjet head 19 may be provided with a corresponding number of piezoelectric elements, and the chemical solution may be discharged onto the substrate 50 through each of the nozzles by operation of each of the piezoelectric elements. That is, the chemical solution may be discharged onto the substrate 50 through each of the nozzles by the operation of each of the piezoelectric elements. Each of the chemical solution discharged from each of the nozzles may be independently controlled by control of a voltage applied to each of the piezoelectric elements.

If the chemical solution from the inkjet head 19 cannot be discharged to a correct position on the substrate 50, it may be determined as a discharge defect, so in the chemical resolution discharge using the inkjet head 19, it must be discharged to the correct position on the substrate 50. For example, each of the chemical solution discharged from the inkjet head 19 must be accurately discharged to each of pixels formed on the substrate 50.

Accordingly, maintenance for confirming whether the chemical solution is discharged from the inkjet head 19 at the correct position and correcting it may be performed at any time. The maintenance may be mainly performed by measuring a discharge position of the chemical solution discharged from the inkjet head 19, that is, discharge dot.

The measurement unit 23 may be provided in the maintenance unit 13. The measurement unit 23 may be provided to measure the discharge dot of the chemical solution discharged from the inkjet head 19, and may be provided to have a structure of supplying a test film as a test substrate. Accordingly, the maintenance of the inkjet head 19 may be performed by placing the inkjet head 19 on the measurement unit 23 and then discharging the chemical solution to the test film of the measurement unit 23, and then confirming the discharge dot for the chemical solution discharged to the test film, and correcting a position of each nozzle of the inkjet head 19 based on the result. The measurement unit 23 may include an assembly for processing reference point. For example, the measuring unit 23 may be referred to as the assembly for processing reference point.

However, in the maintenance, the measurement unit 23 must be accurately set and the inkjet head 19 must be accurately positioned on the measurement unit 23 to discharge the chemical solution, so that the discharge dot for the inkjet head 19 can be more accurately measured. An example of the measurement unit 23 may include a jetting on film (“JOF”) unit that supplies a test film in which a chemical solution is discharged when measuring the discharge dot.

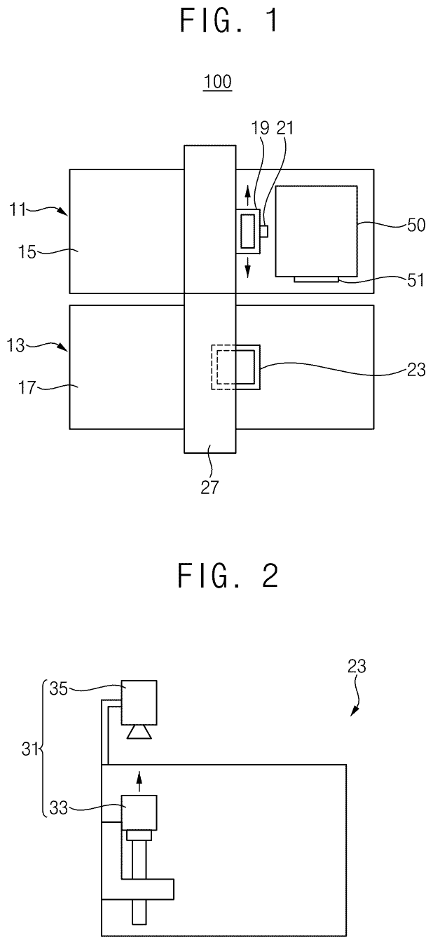

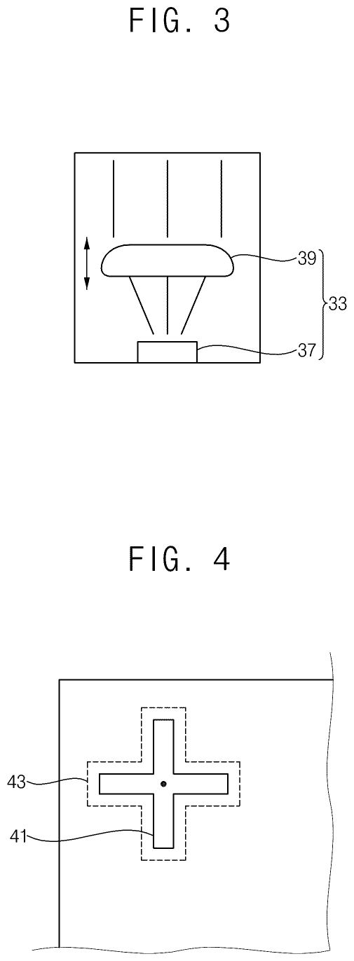

FIG. 2 is a schematic diagram for explaining a reference point processing unit in the apparatus of FIG. 1. FIG. 3 is a schematic diagram for describing a reference point generating unit in the reference point processing unit of FIG. 2. FIG. 4 is a schematic diagram for describing a first reference point and a second reference point generated by using the reference point processing unit of FIG. 2.

Referring to FIGS. 1, 2, 3, and 4, the reference point processing unit 31 in the apparatus 100 according to embodiments may have a structure of generating and confirming a reference point provided when the measurement unit 23 is set and when the discharge dot is measured. The reference point processing unit 31 may be provided to be disposed in the maintenance unit 13, and in particular, may be provided to be fixed to the measurement unit 23 in the maintenance unit 13. As mentioned above, as the measurement unit 23 may be a JOF unit, the reference point processing unit 31 may be provided to be fixed to the JOF unit.

The reference point processing unit 31 may include a reference point generating unit 33 and a reference point confirming unit 35, and the reference point generating unit 33 may be provided to generate at least two reference points of different sizes having a same central axis at a same position, and the reference point confirming unit 35 may be provided to confirm all of the at least two reference points using only one in one place. For example, the reference point generating unit 33 may be provided to generate a first reference point 41 provided as a reference point when measuring the discharge dot of the chemical solution discharged from the inkjet head 19 and a second reference point 43 provided as a reference point when setting the measurement unit 23 used to measure the discharge dot. The reference point processing unit 31 may be provided to confirm both the first reference point 41 and the second reference point 43 using only one in one place. In particular, the reference point processing unit 31 may be provided to form at least two reference points to have a size suitable for a purpose.

The reference point generating unit 33 may be provided to generate a first reference point 41 and a second reference point 43, and the first reference point 41 and the second reference point 43 may have different sizes and a same central axis at a same position. The reference point generating unit 33 may be provided to generate at least two reference points to have a same shape, and may be provided to generate the first reference point 41 and the second reference point 43 to have a same shape. As mentioned above, the first reference point 41 may be provided as a reference point when measuring the discharge dot of the chemical solution discharged from the inkjet head 19, and the second reference point 43 may be provided as a reference point when the measurement unit 23 is set, so the reference point generating unit 33 may be provided to generate the second reference point 43 relatively larger than the first reference point 41.

The reference point generating unit 33 may be provided to have a structure including a beam projection 37 and a size variable unit 39, and the beam projection 37 may be provided to generate one reference point, and the size variable unit 39 may be provided to vary one reference point generated by the beam projection 37 to have at least two different sizes. Examples of the size variable unit 39 may include a lens capable of adjusting focus through movement. For example, the reference point generating unit 33 may include a beam projection 37 that generates one reference point, and a size variable unit 39 that changes the one reference point generated by the beam projection 37 to a first reference point 41 and a second reference point 43 having different sizes. For example, the size variable unit 39 may change the one reference point to the first reference point 41 having a relatively small size and the second reference point 43 having a relatively large size.

The reference point confirming unit 35 may be provided to acquire an image for at least two reference points when the at least two reference points are confirmed, and an example of the reference point confirming unit 35 may be a vision camera. As the at least two reference points are generated to have a same shape and have a same center axis at a same position, the reference point confirming unit 35 may also be provided to use only one in one place. As the reference point confirming unit 35 may be provided to use only one of the at least two reference points in one place, only one vision camera as the reference point confirming unit 35 may be provided, and may be provided to be located in one place. The reference point confirming unit 35 may be provided to be fixed to the measurement unit 23, and for example, may be provided to be fixed to the JOF unit. As one vision camera as the reference point confirming unit 35 may be provided, different sizes for at least two reference points may be within a range that satisfies a FOV of the vision camera. That is, different sizes for the first reference point 41 and the second reference point 43 may be within a range that satisfies the FOV of the vision camera as the reference point confirming unit 35. In addition, the reference point generating unit 33 may also be provided to be fixed to the measurement unit 23, and for example, may be provided to be fixed to the JOF unit. The reference point confirming unit 35 may be provided to be fixed to the JOF unit or the like, but as the reference point confirming unit 35 may include the vision camera, it may be replaced with a vision camera 21 disposed in the inkjet head 19. That is, the vision camera 21, and/or the like disposed in the inkjet head 19 may also be used as the reference point confirming unit 35.

As mentioned above, the reference point processing unit 31 may be provided to have a structure fixed to the measurement unit 23. In this case, the reference point generating unit 33 may be provided to generate at least two reference points from below the reference point confirming unit 35 toward the reference point confirming unit 35, and the reference point confirming unit 35 may be provided to confirm the at least two reference points from above the reference point generating unit 33 toward the reference point generating unit 33. When the reference point processing unit 31 is provided to be fixed to the JOF unit, which is the measurement unit 23, the reference point generating unit 33 may be provided to generate the first reference point 41 and the second reference point 43 from bottom of the JOF unit to top of the JOF unit, and the reference point confirming unit 35 may be provided to confirm the first reference point 41 and the second reference point 43 from the top of the JOF unit to the bottom of the JOF unit facing the reference point generating unit 33. The reference point generating unit 33 and the reference point confirming unit 35 may be provided to face each other vertically. For example, when provided to be fixed to the JOF unit, which is the measurement unit 23, the reference point generating unit 33 and the reference point confirming unit 35 may be provided to have a structure to face each other vertically with a test film therebetween.

As described above, in this disclosure, the at least two reference points, the first reference point 41 and the second reference point 43, which have a same central axis at a same position may be generated, and the at least two reference points including the first reference point 41 and the second reference point 43 may be easily confirmed even when only one reference point confirming unit 35 is used, so that position setting of the measurement unit 23 and the discharge dot measurement of the inkjet head 19 may be performed more easily and accurately. Accordingly, in this disclosure, it may be possible to manage the inkjet head 19 so that the chemical solution can be discharged with a more accurate discharge dot.

Hereinafter, a chemical solution discharge method according to embodiments will be described.

First, the maintenance on the inkjet head 19 may be performed. The maintenance of the inkjet head 19 is to confirm whether the chemical solution discharged from the inkjet head 19 is discharged at a correct position. The maintenance of the inkjet head 19 may be performed by discharging the chemical solution to the measurement unit 23 to confirm the discharge dot.

Accordingly, in the maintenance of the inkjet head 19, the inkjet head 19 may be placed on the measurement unit 23 provided in the maintenance unit 13. And before measuring the discharge dot of the chemical solution discharged from the inkjet head 19, whether the measurement unit 23 is set correctly may be confirmed.

Accordingly, in this disclosure the second reference point 43 may be generated using the reference point generating unit 33, and the second reference point 43 may be confirmed using the reference point confirming unit 35 to perform setting of the measurement unit 23. That is, it may be confirmed whether the measuring unit 23 is set at a predetermined position based on the second reference point 43.

And when the setting for the measurement unit 23 is performed, in this disclosure, it may be confirmed whether the chemical solution discharged from the inkjet head 19 is correctly discharged at a predetermined position. That is, the discharge dot for the chemical solution discharged from the inkjet head 19 may be confirmed. The confirming of the discharge dot may be performed by generating the first reference point 41 using the reference point generating unit 33, and confirming the first reference point 41 using the reference point confirming unit 35. Here, the first reference point 41 may be generated relatively small in size compared to the second reference point 43, but may be generated to have a same shape and have a same central axis at a same position as the second reference point. In addition, confirming the first reference point 41 and the second reference point 43 may be achieved by using a vision camera of only one in one place.

Subsequently, the inkjet head may be located to an accurate position by confirming the first reference point 41, then the discharge dot of the liquid solution may be confirmed by discharging the chemical solution from the inkjet head 19 to the measurement unit 23, and based on the result, correction of position, performance, and/or the like of the nozzles in the inkjet head 19 may be performed.

In this way, in the chemical solution discharge method of this disclosure, the at least two reference points, the first reference point 41 and the second reference point 43, which have a same central axis at a same location may be generated and the at least two reference points including the first reference point 41 and the second reference point 43 may be easily confirmed even when using only one reference point confirming unit 35.

The assembly, the apparatus and the method of this disclosure may be actively applied to manufacture of display element requiring high resolution as the assembly, the apparatus, and the method may perform more accurate and easier maintenance for the inkjet head to perform the chemical solution discharge process for each of more densely arranged pixels.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. An assembly for processing a reference point comprising:
a reference point generating unit configured to generate at least two reference points of different sizes having a same central axis at a same position; and
a reference point confirming unit configured to confirm both of the at least two reference points using only one in one place.

2. The assembly of claim 1, wherein the reference point generating unit is configured to generate the at least two reference points to have a same shape.

3. The assembly of claim 1, wherein the reference point generating unit includes a beam projection for generating one reference point and a size variable unit for changing the one reference point generated by the beam projection to have at least two different sizes.

4. The assembly of claim 1, wherein the reference point confirming unit includes a vision camera, and different sizes for the at least two reference points are within a range satisfying a field of view (“FOV”) of the vision camera

5. The assembly of claim 1, wherein the reference point generating unit is configured to generate the at least two reference points from below the reference point confirming unit toward the reference point confirming unit, and the reference point confirming unit is configured to confirm the at least two reference points from above the reference point generating unit toward the reference point generating unit.

6. An apparatus for dispensing chemical solution comprising:
a printing unit configured to perform a chemical solution discharge process using an inkjet head;
a maintenance unit that maintenance is performed on the inkjet head; and
a reference point confirming unit including a reference point generating unit and a reference point confirming unit, wherein the reference point generating unit is configured to generate a first reference point provided as a reference point when measuring discharge dot of chemical solution discharged from the inkjet head and a second reference point provided as a reference point when setting a measurement unit used for measuring the discharge dot, the reference point generating unit is configured to generate the first reference point and the second reference point to have a same central axis at a same position while having different sizes, and the reference point confirming unit is configured to confirm both the first reference point and the second reference point using only one in one place.

7. The apparatus of claim 6, wherein the reference point generating unit is configured to generate the first reference point and the second reference point to have a same shape.

8. The apparatus of claim 6, wherein the reference point generating unit is configured to generate the second reference point relatively larger than the first reference point.

9. The apparatus of claim 6, wherein the reference point generating unit includes a beam projection for generating one reference point and a size variable unit for changing the one reference point generated by the beam projection into the first reference point and the second reference point having different sizes.

10. The apparatus of claim 6, wherein the reference point confirming par includes a vision camera, and different sizes of the first reference point and the second reference point are within a range satisfying a FOV of the vision camera.

11. The apparatus of claim 6, wherein the printing unit and the maintenance unit are disposed in parallel along a direction vertical to a transfer direction of a substrate when the chemical solution is discharged, the inkjet head is configured to slide on a gantry extending along the printing unit and the maintenance unit, and the reference point processing unit is provided in the maintenance unit.

12. The apparatus of claim 11, wherein the measurement unit is configured to be disposed in the maintenance unit, and includes a jetting on film (“JOF”) unit configured to supply a test film on which the chemical solution is discharged when the discharge dot is measured.

13. The apparatus of claim 12, wherein the reference point processing unit is fixed to the JOF unit.

14. The apparatus of claim 13, wherein the reference point generating unit in the reference point processing unit is configured to generate the first reference point and the second reference point from bottom of the JOF unit to top of the JOF unit, and the reference point confirming unit is configured to confirm the first reference point and the second reference point from the top of the JOF unit to the bottom of the JOF unit facing the reference point generating unit.

15. A method for dispensing chemical solution, the method comprising:
setting a measurement unit used to measure discharge dot of chemical solution discharged from an inkjet head based on a second reference point; and
measuring the discharge dot of the chemical solution discharged from the inkjet head based on a first reference point using the measuring unit,
wherein the first reference point and the second reference point have different sizes and are generated to have a same central axis at a same position, and both the first reference point and the second reference point are confirmed using one reference point confirming unit in one place.

16. The method of claim 15, wherein the first reference point and the second reference point have a same shape.

17. The method of claim 15, wherein the second reference point is relatively larger than the first reference point.

18. The method of claim 15, wherein the first reference point and the second reference point are generated by changing one reference point generated by beam projection to have different sizes.

19. The method of claim 15, wherein the first reference point and the second reference point are confirmed by using one vision camera disposed in one place, and different sizes of the first reference point and the second reference point are within a range satisfying a FOV of the vision camera.

20. The method of claim 15, wherein the first reference point and the second reference point are configured to be generated from bottom of the measurement unit to top of the measurement unit, and are configured to be confirmed from the top of the measurement unit to the bottom of the measurement unit.
